(19) United States
(12) Patent Application Publication
(10) Pub. No.: US 2012/0153392 A1
(43) Pub. Date: Jun. 21, 2012

(54) MANUFACTURING METHOD FOR SEMICONDUCTOR STRUCTURE, AND PIXEL STRUCTURE AND MANUFACTURING METHOD FOR THE SAME

(76) Inventors: Chih-Hung CHENG, Tainan City (TW); Isaac Wing-Tak Chan, Hsinchu City (TW)

(21) Appl. No.: 13/053,691

(22) Filed: Mar. 22, 2011

(30) Foreign Application Priority Data
Dec. 17, 2010 (TW) 99144574

(51) Int. Cl. H01L 29/786; H01L 21/336; H01L 21/20

(52) U.S. Cl. 257/347; 438/478; 438/151; 257/E21.09; 257/E29.273; 257/E21.411

(57) ABSTRACT

A manufacturing method for a semiconductor structure, and a pixel structure and a manufacturing method for the same are provided. The manufacturing method for the semiconductor structure includes following steps. A substrate is provided. A first conductive layer is formed and patterned by using a first mask patterned. A first material film, including a first semiconductor layer, is formed and patterned by using a second mask. A second conductive layer is formed and patterned by using a third mask. A second material film, including a first dielectric layer, a second semiconductor layer and a second dielectric layer, is formed and patterned with using a fourth mask. The second dielectric layer is pattern by using a fifth mask. A third material film, including a third conductive layer, is formed and patterned by using a sixth mask.

This application claims the benefit of Taiwan application Serial No. 99144574, filed Dec. 17, 2010, the subject matter of which is incorporated herein by reference.

### BACKGROUND

1. Technical Field

The disclosure relates in general to a semiconductor structure and a manufacturing method for the same, and more particularly to a pixel structure and a manufacturing method for the same.

2. Related Art

In a semiconductor process, various elements such as an top gate transistor and a bottom gate transistor are formed on a surface of a substrate. The formation of the top gate transistor follows the formation of the bottom gate transistor in general manufacturing method. Otherwise, the formation of the bottom gate transistor follows the formation of the top gate transistor. In other words, the top gate transistor and the bottom gate transistor are formed separately in order. Besides, patterning the films in the elements needs different masks respectively. Thus, the cost is high and the process is complex.

### SUMMARY

The disclosure is directed to a manufacturing method for a semiconductor structure, and a pixel structure and a manufacturing method for the same. It has easier process and lower cost than prior art.

According to an aspect of the present disclosure, a manufacturing method for a semiconductor structure is provided. The manufacturing method for a semiconductor structure comprises the following steps. A substrate is provided. The substrate comprises a first region, a second region and a third region. A first conductive layer is formed and is patterned by utilizing a first mask to be disposed on the first region. The first material layer is formed and is patterned by utilizing a second mask. The first material layer comprises a first semiconductor layer. The first semiconductor layer is disposed on the second region. A second conductive layer is formed and is patterned by utilizing a third mask to make the second conductive layer be disposed on the first semiconductor layer and the third region. The second conductive layer which is on the first semiconductor layer forms a first conductive member and a second conductive member separated from the first conductive member. The second material layer is formed and is patterned by utilizing a fourth mask. The second material layer comprises a first dielectric layer, a second semiconductor layer and a second dielectric layer. The first dielectric layer is disposed on the second conductive layer which is on the second region and the third region. The second semiconductor layer is disposed on the first dielectric layer which is on the third region. The second dielectric layer is disposed on the second semiconductor layer. The second dielectric layer is patterned by utilizing a fifth mask to form a first opening in the second dielectric layer. The second semiconductor layer is exposed by the first opening. Form and utilize a sixth mask to pattern the third material layer. The third material layer comprises a third conductive layer. The third conductive layer is disposed on the first dielectric layer which is on the second region and the second semiconductor layer exposed by the first opening. The third material layer on the third region forms a third conductive member and a fourth conductive member separated from the third conductive member.

According to another aspect of the present disclosure, a manufacturing method for a pixel structure is provided. The manufacturing method for a pixel structure comprises the following steps. A substrate is provided. The substrate comprises a first region, a second region and a third region. A first conductive layer is formed and is patterned by utilizing a first mask to make the first conductive layer be disposed on the first region. The first material layer is formed and is patterned by utilizing a second mask.

The first material layer comprises a first semiconductor layer. The first semiconductor layer is disposed on the second region. A second conductive layer is formed and is patterned by utilizing the third mask to make the second conductive layer be disposed on the first semiconductor layer and the third region. The second conductive layer which is on the first semiconductor layer forms a first conductive member and a second conductive member separated from the first conductive member. The second material layer is formed and is patterned by utilizing a fourth mask. The second material layer comprises a first dielectric layer, a second semiconductor layer and a second dielectric layer. The first dielectric layer is disposed on the second conductive layer which is on the second region and the third region. The second semiconductor layer is disposed on the first dielectric layer which is on the third region. The second dielectric layer is disposed on the second semiconductor layer. The second dielectric layer is patterned by utilizing a fifth mask to form a first opening in the second dielectric layer. The second semiconductor layer is exposed by the first opening. A third material layer is formed and is patterned by utilizing a sixth mask. The third material layer comprises a third conductive layer. The third conductive layer is disposed on the first dielectric layer which is on the second region and extended on the first conductive layer and is on the second semiconductor layer exposed by the first opening. The third material layer on the third region forms a third conductive member and a fourth conductive member separated from the third conductive member. The first semiconductor layer, the second conductive layer, the first dielectric layer and the third conductive layer which are on the second region constitute a top gate transistor. The second conductive layer, the first dielectric layer, the second semiconductor layer and the third conductive layer which are on the third region constitute a bottom gate transistor.

According to still another aspect of the present disclosure, a pixel structure is provided. The pixel structure comprises a substrate, a first conductive layer, a first material layer, a second conductive layer, a second material layer, a third material layer. The substrate comprises a first region, a second region and a third region. The first conductive layer is on the first region. The first material layer comprises a first semiconductor layer. The first semiconductor layer is on the second region. The second conductive layer is on the first semiconductor layer and the third region. The second conductive layer on the first semiconductor layer forms a first conductive member and a second conductive member separated from the first conductive member. The second material layer comprises a first dielectric layer, a second semiconductor layer and a second dielectric layer. The first dielectric layer is disposed on the second conductive layer which is on the second region and the third region. The second semiconductor layer is disposed on the first dielectric layer which is on the third region. The second dielectric layer is disposed on the second semiconductor layer and has a first opening which exposes the second semiconductor. A third material layer comprises a third conductive layer. The third conductive layer is disposed on the first dielectric layer which is on the second region and the second semiconductor layer is exposed by the first opening. The third material layer on the third region forms a third conductive member and a fourth conductive member separated from the third conductive member. The first semiconductor layer, the second conductive layer, the first dielectric layer and the third conductive layer which are on the second region constitute a top gate transistor. The second conductive layer, the first dielectric layer, the second semiconductor layer and the third conductive layer which are on the third region constitute a bottom gate BCP transistor.

The above and other aspects of the disclosure will become better understood with regard to the following detailed description but non-limiting embodiment(s). The following description is made with reference to the accompanying drawings.

### BRIEF DESCRIPTION OF THE DRAWINGS

FIGS. 1-7 are schematic views showing a manufacturing method for semiconductor structure according to the first embodiment of the disclosure.

FIGS. 8-9 are schematic views showing partial steps for manufacturing semiconductor structure according to the second embodiment of the disclosure.

### DETAILED DESCRIPTION OF THE DISCLOSURE

### First Embodiment

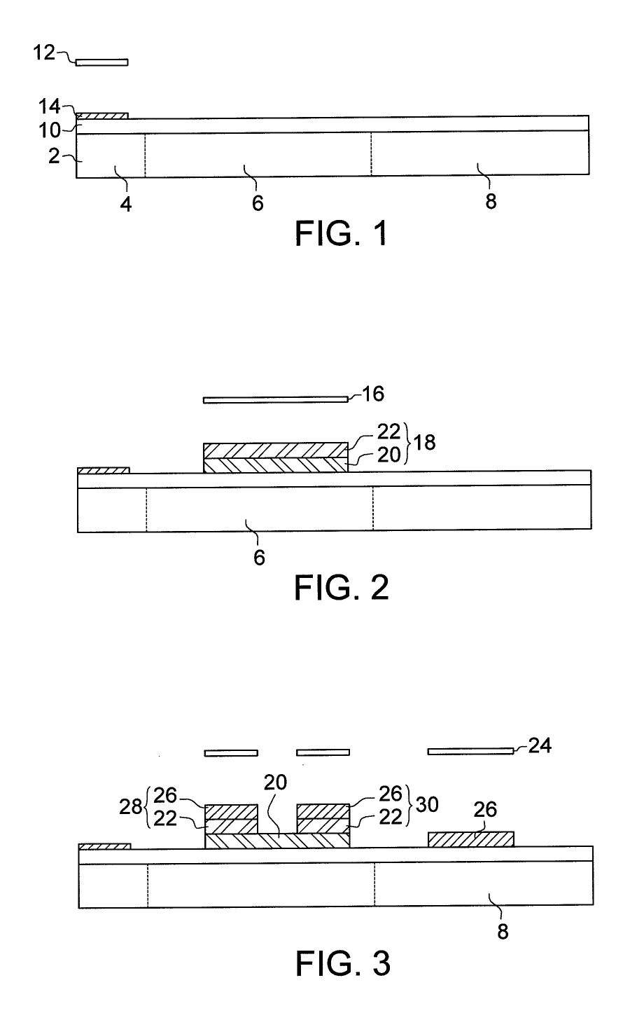

FIGS. 1-7 are schematic views showing a manufacturing method for a semiconductor structure according to the first embodiment of the disclosure. Referring to FIG. 1, a substrate 2 is provided. For example, the substrate 2 comprises glass, metal, plastic or silicon-based material. The substrate 2 may be transparent. The substrate 2 also may be a flexible substrate. The substrate 2 may comprise a first region 4, a second region 6 and a third region 8. A buffer layer 10 may be formed on the substrate 2. The buffer layer 10 includes, for example, silicon dioxide, silicon nitride or other suitable materials.

Referring to FIG. 1, a first conductive layer 14 is formed and is patterned by utilizing a first mask 12 to make the first conductive layer 14 be disposed on the first region 4. The patterning method may include a lithography process. The first conductive layer 14 may include indium tin oxide or other transparent conductive materials.

Referring to FIG. 2, the first material layer 18 is formed and is patterned by utilizing a second mask 16. The patterning method may include a lithography process. The first material layer 18 may include a first semiconductor layer 20 and a first doped layer 22. In the patterned first material 18, the first semiconductor layer 20 and the first doped layer 22 may be disposed on the second region 6. The first semiconductor layer 20 may include amorphous silicon or metallic oxide. In some embodiments, the first doped layer 22 may have N+ conductivity. However, the disclosure is not limited thereto. In other embodiments, the first doped layer 22 also may have P+ conductivity.

Accordingly, the step of forming and utilizing the first mask 12 to pattern the first conductive layer 14 is between the step of providing the substrate 2 and the step of forming and utilizing the second mask 16 to pattern the first material layer 18. However, the disclosure is not limited thereto.

Referring to FIG. 3, a second conductive layer 26 is formed and is patterned by utilizing a third mask 24 to make the second conductive layer 26 be disposed on the third region 8. The second conductive layer 26 includes, for example, metal. Besides, the third mask 24 also may be utilized to pattern the first doped layer 22. In an embodiment, the second conductive layer 26 and the first doped layer 22 are patterned by utilizing the third mask 24 at the same time. The patterning method may include a lithography process. The first conductive member 28 and the second conductive member 30 separated from the first conductive member 28 are formed by the first doped layer 22 and the second conductive layer 26 on the first semiconductor layer 20. In some embodiments, the first doped layer 22 is not formed, thus the first conductive member 28 and the second conductive member 30 on the first semiconductor layer 20 are only formed by the second conductive layer 26.

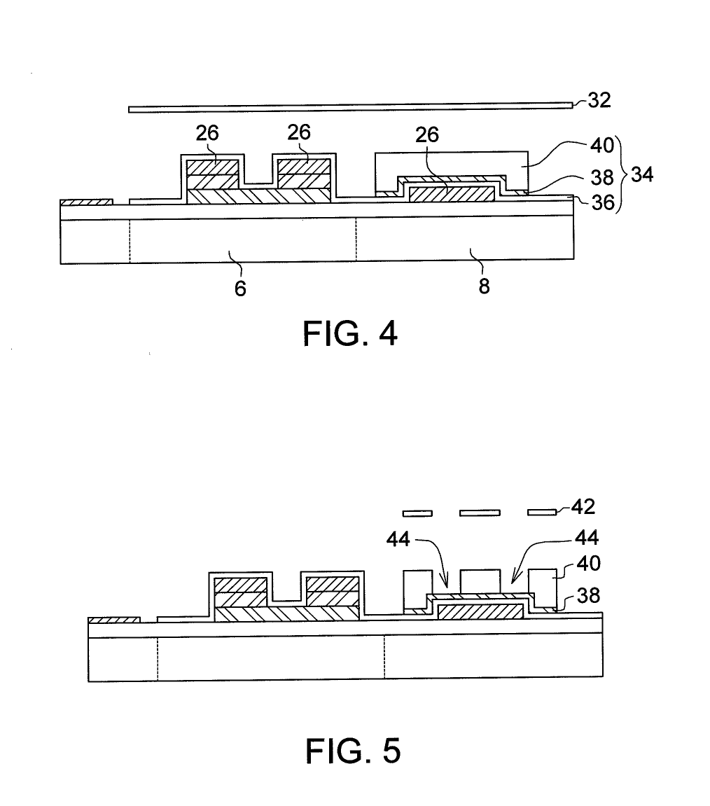

Referring to FIG. 4, a second material layer 34 is formed and is patterned by utilizing a fourth mask 32. The patterning method may include a lithography process. The second material layer 34 may include a first dielectric layer 36, a second semiconductor layer 38 and a second dielectric layer 40. In the patterned second material layer 34, the first dielectric layer 36 is disposed on the second conductive layer 26 on the second region 6 and the third region 8. The second semiconductor layer 38 is on the first dielectric layer 36 which is on the third region 8. Besides, the second dielectric layer 40 is on the second semiconductor layer 38. The first dielectric layer 36 may include silicon nitride. The second semiconductor layer 38 may include amorphous silicon or metallic oxide. The second dielectric layer 40 may include silicon nitride. In the embodiment, the structure showed in the FIG. 4 is formed by adjusting the etching selectivity in the etching process for the first dielectric layer 36, the second semiconductor layer 38 and the second dielectric layer 40.

Referring to FIG. 5, the second dielectric layer 40 is patterned by utilizing a fifth mask 42 to form a first opening 44 in the second dielectric layer 40 to expose the second semiconductor layer 40. The patterning method may include a lithography process.

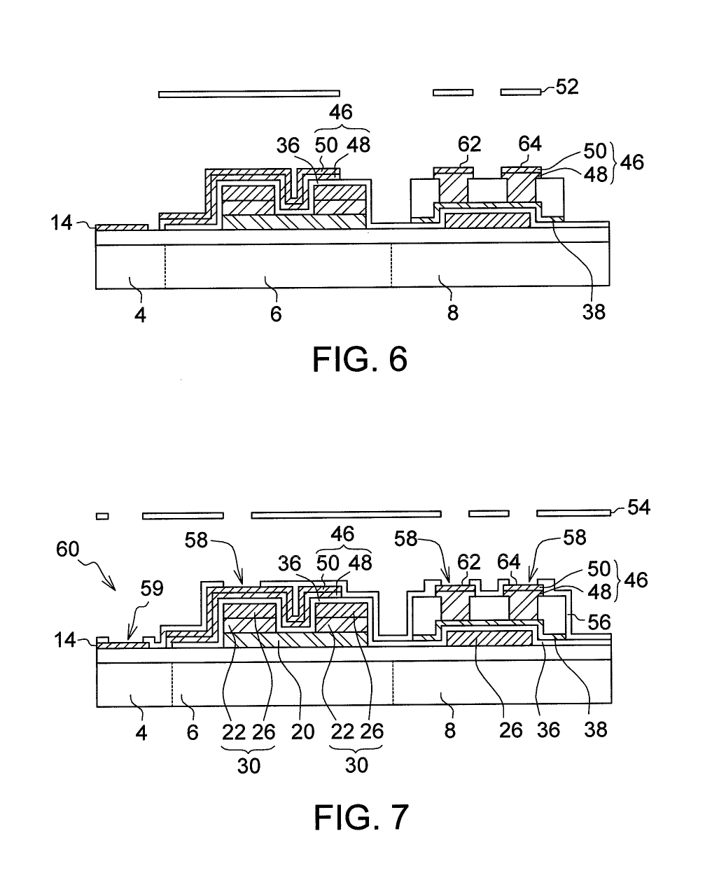

Referring to FIG. 6, the third material layer 46 is formed and is patterned by utilizing a sixth mask 52. The patterning method may include a lithography process. In the patterned third material layer 46 includes, for example, the second doped layer 48 and the third conductive layer 50. The third conductive layer 50 may disposed on the second doped layer 48. In the patterned third material layer 46, for example, the second doped layer 48 and the third conductive layer 50 are disposed on the first dielectric layer 36 which is on the second region 6 and on the second semiconductor layer 38 which is on the third region 8. The third conductive member 62 and the fourth conductive member 64 separated from the second conductive member 62 are formed by the third material layer 46 on the third region 8. In some embodiments, the second doped layer 48 is not formed. Thus, the third conductive member 62 and the fourth conductive member 64 are only formed by the third conductive layer 50. Besides, the third material layer 46 on the first region 4 and the second region 6 only have the third conductive layer 50, and does not have the second doped layer 48. The second doped layer 48 may have N+ conductivity. However, the disclosure is not limited thereto. In other embodiments, the second doped layer 48 also may have P+ conductivity. The third conductive layer 50 may include metal.

Referring to FIG. 7, a third dielectric layer 56 is formed and is patterned by utilizing a seventh mask 54 to make the third dielectric layer 56 have a second opening 58 and a third opening 59. The third material layer 46 is exposed by the second opening 58 and the first conductive layer 14 is exposed by the third opening 59. The patterning method may include a lithography process. In an embodiment, the third conductive layer 50 of the third material layer 46 may be exposed by the second opening 58. In some embodiments, the step of forming and utilizing the seventh mask 54 to pattern the third dielectric layer 56 may be omitted.

Referring to FIG. 7, the semiconductor structure 60 may be a pixel structure which may be applied on the X-ray photo sensor or active-matrix organic LED etc. For example, the first conductive layer 14 on the first region 4 may be pixel electrode. The first semiconductor layer 20, the first doped layer 22, the second conductive layer 26, the first dielectric layer 36 and the third conductive layer 50 (and the second doped layer 48) of the third material layer 46 which are on the second region 6 constitute a top gate transistor. For example, the first conductive member 28 and the second conductive member 30 formed by the second conductive layer 26 (and the first doped layer 22) may act as the source and the drain respectively. The third conductive layer 50 (and the second doped layer 48) of the third material layer 46 may act as the gate. In an embodiment, the first semiconductor layer 20 on the second region 6 has silicon-based material, and the first doped layer 22 is formed on the first semiconductor layer 20 to decrease the contact resistance between the first semiconductor layer 20 and the second conductive layer 26 and improve the conductive characteristics.

The second conductive layer 26, the first dielectric layer 36, the second semiconductor layer 38 and the third conductive layer 50 (and the second doped layer 48) which are on the third region 8 constitute a bottom gate transistor, exemplarily, a bottom gate BCP transistor. For example, the third conductive member 62 and the fourth conductive member 64 formed by the third conductive layer 50 (and the second doped layer 48) may act as the source and the drain respectively. The second conductive layer 26 may act as the gate. In an embodiment, the second semiconductor layer 38 on the third region 8 has silicon-based material, and the second doped layer 48 is formed on the second semiconductor layer 38 to decrease the contact resistance between the second semiconductor layer 38 and the third conductive layer 50 and improve the conductive characteristics.

In an embodiment, for example, one of the source and the drain of the top gate transistor is electrically connected to the gate of the bottom gate transistor. One of the source and the drain of the bottom gate transistor is electrically connected to pixel electrode.

In the embodiment, the semiconductor structure 60 may include the top gate transistor and the bottom gate BCP transistor. The top gate transistor has the advantage of high carrier mobility. The bottom gate transistor BCP has the advantage of low leakage current and high reliability. Thus, the semiconductor structure 60 has great effects. Besides, it may utilize a few masks (such as the first mask 12 to the sixth mask 52) to manufacture the semiconductor structure 60, thus the method of manufacturing is easy and has low cost.

In the embodiment, the sequence of the steps may be adjusted depending on actual conditions. For example, the step of forming and utilizing the first mask to pattern the first conductive layer may be adjusted to be performed after the forming of the top gate transistor and the bottom gate transistor. In other words, the step of forming and utilizing the first mask to pattern the first conductive layer is performed finally. Thus, the manufacturing method of the semiconductor structure has high process flexibility. The second embodiment is described as following.

### Second Embodiment

The difference between the second embodiment and the first embodiment is that the step of forming and utilizing the first mask to pattern the first conductive layer is performed after the step of forming and utilizing the sixth mask to pattern the third material layer in the second embodiment. That is, the step of forming and utilizing the first mask to pattern the first conductive layer is performed finally.

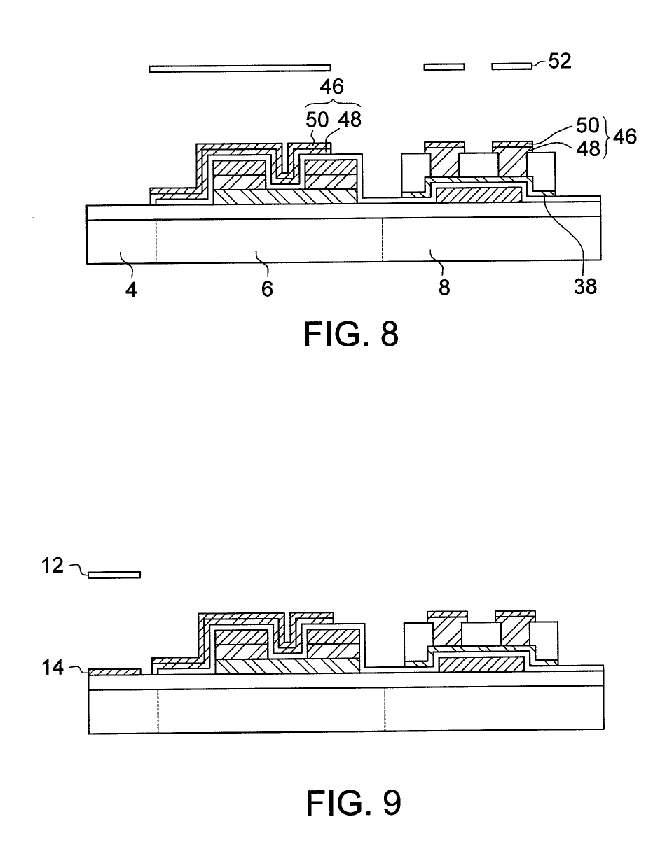

FIGS. 8-9 are schematic views showing partial steps for manufacturing the semiconductor structure according to the second embodiment of the disclosure. In the second embodiment, after the third material 46 is formed and is patterned by utilizing the sixth mask 52 (FIG. 8), the first conductive layer 14 is formed and is patterned by utilizing the first mask 12 (FIG. 9). The manufacturing step shown in FIG. 7 may be performed to form the semiconductor structure 60 according to requirements.

The semiconductor structure such as the pixel structure disclosed by the embodiments has the top gate transistor and the bottom gate transistor, for example, bottom gate BCP transistor, thus has great effects. It utilizes a few (six) masks to form the semiconductor structure, thus the manufacturing method is easy and has low cost. The sequence of the steps may be adjusted depending on actual conditions, thus the process flexibility is high.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method for a semiconductor structure, comprising:
providing a substrate comprising a first region, a second region and a third region;
forming and utilizing a first mask to pattern a first conductive layer to make the first conductive layer be disposed on the first region;
forming a first material layer comprising a first semiconductor layer and utilizing a second mask to pattern the first material layer to make the first semiconductor layer be disposed on the second region;
forming and utilizing a third mask to pattern a second conductive layer to make the second conductive layer be disposed on the first semiconductor layer and the third region, the second conductive layer which is on the first semiconductor layer forming a first conductive member and a second conductive member separated from the first conductive member;
forming a second material layer comprising a first dielectric layer, a second semiconductor layer and a second dielectric layer, utilizing a fourth mask to pattern the second material layer to make the first dielectric layer be disposed on the second conductive layer which is on the second region and the third region, the second semiconductor layer be disposed on the first dielectric layer which is on the third region and the second dielectric layer be disposed on the second semiconductor layer;
utilizing a fifth mask to pattern the second dielectric layer to form a first opening in the second dielectric layer, the second semiconductor layer exposed by the first opening; and
forming a third material layer comprising a third conductive layer, utilizing a sixth mask to pattern the third material layer to make the third conductive layer be disposed on the first dielectric layer which is on the second region and the second semiconductor layer exposed by the first opening, wherein the third material layer on the third region forms a third conductive member and a fourth conductive member separated from the third conductive member.

2. The manufacturing method for the semiconductor structure according to claim 1, further comprising forming and utilizing a seventh mask to pattern a third dielectric layer to make the third dielectric layer have a second opening, the third material layer exposed by the second opening.

3. The manufacturing method for the semiconductor structure according to claim 1, wherein the first material layer further comprises a first doped layer between the first semiconductor layer and the second conductive layer, the first doped layer is patterned in the step of utilizing the third mask to pattern the second conductive layer simultaneously, the first conductive member and the second conductive member comprise the first doped layer and the second doped layer respectively.

4. The manufacturing method for the semiconductor structure according to claim 1, wherein the third material layer further comprises a second doped layer between the second semiconductor layer and the third conductive layer on the third region.

5. The manufacturing method for the semiconductor structure according to claim 1, wherein the step of forming and utilizing the mask to pattern the first conductive layer is between the step of providing the substrate and the step of forming and utilizing the mask to pattern the first material layer.

6. The manufacturing method for the semiconductor structure according to claim 1, wherein the step of forming and utilizing the mask to pattern the first conductive layer is performed finally.

7. A manufacturing method for a pixel structure, comprising:
providing a substrate comprising a first region, a second region and a third region;
forming and utilizing a first mask to pattern a first conductive layer to make the first conductive layer be disposed on the first region;
forming a first material layer comprising a first semiconductor layer and utilizing a second mask to pattern the first material layer to make the first semiconductor layer be disposed on the second region;
forming and utilizing a third mask to pattern a second conductive layer to make the second conductive layer be disposed on the first semiconductor layer and the third region, the second conductive layer which is on the first semiconductor layer forming a first conductive member and a second conductive member separated from the first conductive member;
forming a second material layer comprising a first dielectric layer, a second semiconductor layer and a second dielectric layer, utilizing a fourth mask to pattern the second material layer to make the first dielectric layer be disposed on the second conductive layer which is on the second region and the third region, the second semiconductor layer be disposed on the first dielectric layer which is on the third region and the second dielectric layer be disposed on the second semiconductor layer;
utilizing a fifth mask to pattern the second dielectric layer to form a first opening in the second dielectric layer, the second semiconductor layer exposed by the first opening; and
forming a third material layer comprising a third conductive layer, utilizing a sixth mask to pattern the third material layer to make the third conductive layer be disposed on the first dielectric layer which is on the second region and the second semiconductor layer exposed by the first opening, wherein the third material layer on the third region forms a third conductive member and a fourth conductive member separated from the third conductive member;
the first semiconductor layer, the second conductive layer, the first dielectric layer and the third conductive layer which are on the second region constitute a top gate transistor; and
the second conductive layer, the first dielectric layer, the second semiconductor layer and the third conductive layer which are on the third region constitute a bottom gate transistor.

8. The manufacturing method for the pixel structure according to claim 7, wherein the step of forming and utilizing the mask to pattern the first conductive layer is between the step of providing the substrate and the step of forming and utilizing the mask to pattern the first material layer.

9. The manufacturing method for the pixel structure according to claim 7, wherein the step of forming and utilizing the mask to pattern the first conductive layer is performed finally.

10. A pixel structure, comprising:
a substrate comprising a first region, a second region and a third region;
a first conductive layer which is on the first region;
a first material layer comprising a first semiconductor layer which is on the second region;
a second conductive layer which is on the first semiconductor layer and the third region, the second conductive layer on the first semiconductor layer forming a first conductive member and a second conductive member separated from the first conductive member;
a second material layer comprising a first dielectric layer, a second semiconductor layer and a second dielectric layer, the first dielectric layer disposed on the second conductive layer which is on the second region and the third region, the second semiconductor layer disposed on the first dielectric layer which is on the third region, the second dielectric layer disposed on the second semiconductor layer and having a first opening, the second semiconductor layer exposed by the first opening; and
a third material layer comprising a third conductive layer, the third conductive layer disposed on the first dielectric layer which is on the second region and the second semiconductor layer exposed by the first opening, wherein the third material layer on the third region forms a third conductive member and a fourth conductive member separated from the third conductive member,
the first semiconductor layer, the second conductive layer, the first dielectric layer and the third conductive layer which are on the second region constitute a top gate transistor,
the second conductive layer, the first dielectric layer, the second semiconductor layer and the third conductive layer which are on the third region constitute a bottom gate BCP transistor.

11. The pixel structure according to claim 10, further comprising a first doped layer formed on the first semiconductor layer, wherein the first semiconductor layer has silicon-based material.

12. The pixel structure according to claim 11, wherein the first doped layer is between the first semiconductor layer and the second conductive layer on the second region.

13. The pixel structure according to claim 10, further comprising a second doped layer formed on the second semiconductor layer, wherein the second semiconductor layer has silicon-based material.

14. The pixel structure according to claim 13, wherein the second doped layer is between the second semiconductor layer and the third conductive layer on the third region.

15. The pixel structure according to claim 10, further comprising a second doped layer formed on the first dielectric layer which is on the second region.
